(19) United States
(12) Patent Application Publication
(10) Pub. No.: US 2016/0154488 A1
(43) Pub. Date: Jun. 2, 2016

(54) INTEGRATED CONTROLLER SYSTEM FOR VEHICLE

(71) Applicant: HYUNDAI MOTOR COMPANY, Seoul (KR)

(72) Inventor: Sung Un KIM, Yongin-si (KR)

(21) Appl. No.: 14/952,484

(22) Filed: Nov. 25, 2015

(30) Foreign Application Priority Data
Nov. 28, 2014 (KR) 10-2014-0168279

(51) Int. Cl. G06F 3/0354; G06F 3/0488; G06F 3/0482; G06F 3/0481; G06F 3/01; G06F 3/0485

(52) U.S. Cl. CPC G06F 3/03547; G06F 3/016; G06F 3/0485; G06F 3/0482; G06F 3/04817; G06F 3/04883

(57) ABSTRACT

An integrated controller system for a vehicle includes: an information processing device that displays information for driving the vehicle through a display unit; an integrated controller case that can be held with a hand; a front surface control unit located at a front of the case that a holding fingertip contacts and that controls a User Interface (UI) displayed in the display unit; a side surface control unit located at a side surface of the case that a holding fingertip contacts and that can perform scroll control of the UI; a haptic feedback unit that transfers a haptic effect according to the UI control; and a control unit that transfers a control signal according to the UI control to the information processing device.

### CROSS-REFERENCE TO RELATED APPLICATION

This application claims priority to and the benefit of Korean Patent Application No. 10-2014-0168279 filed in the Korean Intellectual Property Office on Nov. 28, 2014, and Korean Patent Application No. 10-2015-0163549 filed in the Korean Intellectual Property Office on Nov. 20, 2015, the entire contents of which are incorporated herein by reference.

### BACKGROUND

(a) Field

The disclosure relates to an integrated controller system for a vehicle, and, more particularly, to an integrated controller system for a vehicle that can be controlled with a fingertip to minimize a driver's attention diversion.

(b) Description of the Related Art

In general, to control the Audio Visual Navigation (AVN) of a vehicle, apparatus using a touch screen and an integrated controller system of a knob/button type, a mouse type, and a rotary method have been widely used.

In a touch screen method, because a user can view and directly control a menu or an icon, the touch screen method represents an intuitive and fast control in a non-driving situation. While driving, however, upon touching the screen, the driver's posture will tend to change and sight line will redirect to a touch screen. This accordingly creates a problem with respect to safe driving.

In a recent trend in which functions within a vehicle increase, an existing knob and button type of control system cannot increase in number of buttons without limit, and there is a problem in that attention by a driver is diverted when manipulating the control system while driving due to complexity of the control system.

The mouse type of control system uses a method of selecting a menu or an icon by directly moving a mouse cursor, and this has intuitive merit. However, when selecting an icon by directly moving the cursor, to a desired point of a User Interface (UI), a user should continue to view the cursor. Thus, there is a drawback in that a user's sight line is diverted. Furthermore, due to a high degree of freedom of the control system, when a vehicle vibrates or when a cursor is clicked while driving, there is a drawback in that intended coordinates may change.

The integrated controller of a rotary method has a form that is familiar to a user, but in order to perform a specific function, the integrated controller of the rotary method has a drawback in that menu entrance and selection (PUSH) consisting of many steps must be performed. That is, in the rotary method, because a UI several steps in depth, there is a problem in that it is difficult to select a subordinate function, and control time is long.

The above information disclosed in this Background section is only for enhancement of understanding of the background of the invention and therefore it may contain information that does not form the prior art that is already known in this country to a person of ordinary skill in the art.

### SUMMARY

The present invention has been made in an effort to provide an integrated controller system for a vehicle having advantages of easy control usability and UI accessibility, and minimizing attention diversion while driving by providing a control system that can provide control using only a fingertip, without moving one's body, and thereby further providing an enhanced UI.

An exemplary embodiment of the present invention provides an integrated controller system for a vehicle that may include an information processing device that displays information for driving the vehicle through a display unit; an integrated controller case that can be held with a hand; a front surface control unit located at a front of the case that a holding fingertip contacts and that controls a User Interface (UI) displayed in the display unit; a side surface control unit located at a side surface of the case that a holding fingertip contacts and that can perform scroll control of the UI; a haptic feedback unit that transfers a haptic effect according to the UI control; and a control unit that transfers a control signal according to the UI control to the information processing device.

The front surface control unit may have a touch pad to control or select a particular UI with orthogonal motion and rotation.

The touchpad may detect a touch location by measuring impedance associated with a finger with an electrode that is under a surface thereof.

The touchpad may receive a menu selection with a double-tap method.

The front surface control unit may have two or more touch and push switch buttons of an array form to control or select the particular UI with orthogonal motion and rotation.

The touch and push switch button may include a push switch formed with a protrusion; a bottom metal electrode disposed at an upper portion of the push switch and formed with a penetration hole corresponding the protrusion; a top metal electrode disposed at an upper portion of the bottom metal electrode; a switch skin disposed at an upper portion of the top metal electrode and receiving a touch; and a touch recognition unit connected to the bottom metal electrode.

The push switch, the bottom metal electrode, the top metal electrode and the switch skin may be sequentially stacked.

The touch recognition unit may recognize the touch by detecting a capacitance between a finger and the bottom metal electrode.

The two or more touch and push switch buttons of the array form may receive a flicking and swiping gesture input by a finger.

The side surface control unit may have an electrode array or a scroll wheel button to receive a scrolling gesture input by a finger.

The haptic feedback unit may include a haptic actuator that is disposed at an upper portion of the case that a palm in a holding state contacts.

The information processing device may display a simple UI that reduces an icon number to a predetermined number or less and that has an enlarged size on a screen of the display unit while a vehicle is driven.

The information processing device may display a cursor on a screen of the display unit, and the cursor may freely move in an entire area of a screen or moves in an icon unit that is displayed on a screen according to a finger control of the front surface control unit.

Another exemplary embodiment of the present invention provides an integrated controller system for a vehicle that may include an information processing device that displays information for driving the vehicle through a display unit; an integrated controller case that can be held with a hand; a front surface control unit located at a front of the case that a holding fingertip contacts and provided with a plurality of touch and push switch button that controls a User Interface (UI) displayed in the display unit; a side surface control unit located at a side surface of the case that a holding fingertip contacts and that can perform scroll control of the UI; a haptic feedback unit that transfers a haptic effect according to the UI control; and a control unit that transfers a control signal according to the UI control to the information processing device, wherein a front surface of the case forms a slanted surface from an upper surface to a lower portion and an inward rounded surface from the slanted surface to a bottom surface, and the front surface control unit is installed at the slanted surface.

The touch and push switch button may include a push switch formed with a protrusion; a bottom metal electrode disposed at an upper portion of the push switch and formed with a penetration hole corresponding the protrusion; a top metal electrode disposed at an upper portion of the bottom metal electrode; a switch skin disposed at an upper portion of the top metal electrode and receiving a touch; and a touch recognition unit connected to the bottom metal electrode.

The front surface control unit may have three touch and push switch buttons corresponding to a forefinger, a middle finger, and a ring finger.

The information processing device may display a simple UI including three icons that have an enlarged size on a screen of the display unit while a vehicle is driven.

The three touch and push switch buttons may be respectively interlocked with the three icons to receive any one icon operation.

According to an exemplary embodiment of the present invention, because a UI can be controlled by a user with only a fingertip without moving a body or a hand, convenience can be improved.

Further, because grip feeling is improved and entire control can be performed within a hand, inconvenience of searching for a control system can be reduced and thus sight line and attention diversion problems can be solved.

Further, a flicking and swipe input of a finger can be performed through a button array that can be touched, and thus a search list having a lot of information can be easily managed.

### BRIEF DESCRIPTION OF THE DRAWINGS

FIG. 1 is a block diagram illustrating a configuration of an integrated controller system for a vehicle according to an exemplary embodiment of the present invention.

FIG. 2 is a perspective view illustrating a configuration of an integrated controller according to a first exemplary embodiment of the present invention.

FIG. 3 is a perspective view illustrating a configuration of an integrated controller according to a second exemplary embodiment of the present invention.

FIG. 4 is a diagram illustrating a configuration of a touch and push switch button according to an exemplary embodiment of the present invention.

FIG. 5 is a diagram illustrating a control method of a touch and push switch button according to an exemplary embodiment of the present invention.

FIG. 6 is a diagram illustrating a simple UI that is displayed in a display unit and a control method of the same according to an exemplary embodiment of the present invention.

FIG. 7 is a perspective view illustrating a configuration of an integrated controller according to a third exemplary embodiment of the present invention.

FIG. 8 is a diagram illustrating a control method of a front surface control unit according to the third exemplary embodiment of the present invention.

FIG. 9 is a diagram illustrating a simple UI that is displayed in a display unit and a control method of the same according to the third exemplary embodiment of the present invention.

### DETAILED DESCRIPTION OF THE EMBODIMENTS

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. Like reference numerals designate like elements throughout the specification.

In addition, in the entire specification, unless explicitly described to the contrary, the word “comprise” and variations such as “comprises” or “comprising” will be understood to imply the inclusion of stated elements but not the exclusion of any other elements. In addition, the terms “-er”, “-or”, and “module” described in the specification mean units for processing at least one function or operation, and can be implemented by hardware components or software components and combinations thereof.

Hereinafter, an integrated controller system for a vehicle according to an exemplary embodiment of the present invention will be described in detail with reference to the drawings.

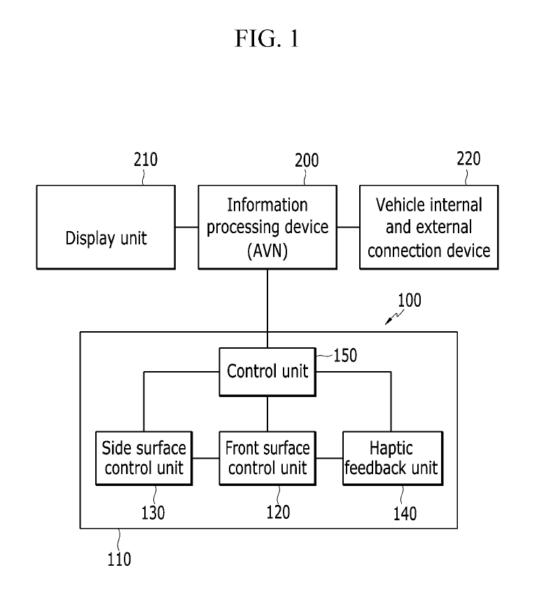

FIG. 1 is a block diagram illustrating a configuration of an integrated controller system for a vehicle according to an exemplary embodiment of the present invention.

As shown in FIG. 1, an integrated controller system for a vehicle according to an exemplary embodiment of the present invention includes a vehicle integrated controller system 100 and an information processing device 200 that executes various functions within a vehicle with control thereof.

The integrated controller 100 includes a front surface control unit 120 and a side surface control unit 130 for centralized control of an information device within the vehicle, and is electrically connected for control of the information processing device 200 that is connected to a display unit 210 and a vehicle internal and external connection device 220.

The information processing device 200 may be an Audio Visual Navigation (AVN) system that processes information for driving of a vehicle.

However, the information processing device 200 according to an exemplary embodiment of the present invention is not limited to an AVN system, and may be a part of an information processing device in which an air conditioning system within a vehicle and an electronic convenience system within various vehicles are integrated.

The display unit 210 may include at least one of a display module provided in a cluster area of the vehicle and a display module in a center fascia area.

The vehicle internal and external connection device 220 includes an internal interface connected to various controllers such as an air conditioning controller and an engine controller within the vehicle, and an external interface that supplies and receives information to and from an external communication network through a USB or a wireless communication module provided within a vehicle. For example, the external interface may supply and receive data to and from an external information device using a wireless communication network such as telematics and WiFi repeaters.

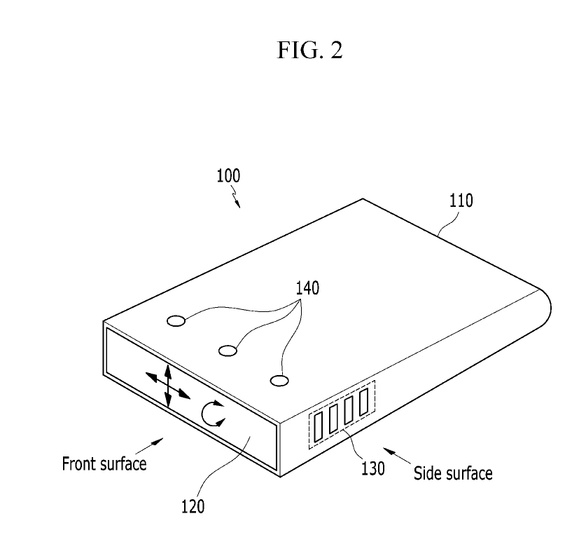

FIG. 2 is a perspective view illustrating a configuration of an integrated controller according to a first exemplary embodiment of the present invention.

As shown in FIG. 2, the integrated controller system 100 includes a case 110, a front surface control unit 120, a side surface control unit 130, a haptic feedback unit 140 and a control unit 170.

The case 110 is formed in a polygon configuration that can be held with a hand to be installed at a periphery of a transmission.

The case 110 has a convenient structure of a size that can be held in the palm of a driver's hand to minimize hand movement when manipulating and to control various functions by only a small operation of a finger.

Hereinafter, in an exemplary embodiment of the present invention, it is assumed that a driver's seat is provided at the left side of the vehicle and thus the integrated controller 100 is controlled with the driver's right hand. However, the present invention is not limited thereto, and when a driver's seat is provided at the right side of the vehicle, the integrated controller 100 may be structured to be controlled with a left hand.

The front surface control unit 120 is located at a front surface of the case 110 which a fingertip of the driver contacts when holding the integrated controller 100.

The front surface control unit 120 is formed with a touchpad to control or select a particular UI with orthogonal motion and rotation by a finger tip.

A touchpad of the front surface control unit 120 measures impedance associated with a finger by an electrode that is formed under a surface thereof to detect touch location. The touchpad may receive a menu selection with a double-tap method.

The side surface control unit 130 is located at a side surface of the case 110 that a fingertip contacts when the integrated controller 100 is held.

The side surface control unit 130 forms an electrode array in a portion that a thumb contacts to change an analog input value such as a change of audio volume, air conditioner air volume, and radio frequency by a scroll input.

The haptic feedback unit 140 is formed with a haptic actuator that is disposed at an upper plane of the case 110 that a palm contacts the integrated controller 100 is held.

The haptic feedback unit 140 transfers a touch indication according to a user's control of the front surface control unit 120 and the side surface control unit 130 to provide feedback for UI control.

The control unit 170 transfers a control signal of the front surface control unit 120 and the side surface control unit 130 according to a UI control that is displayed in the display unit 210 to the information processing device 200.

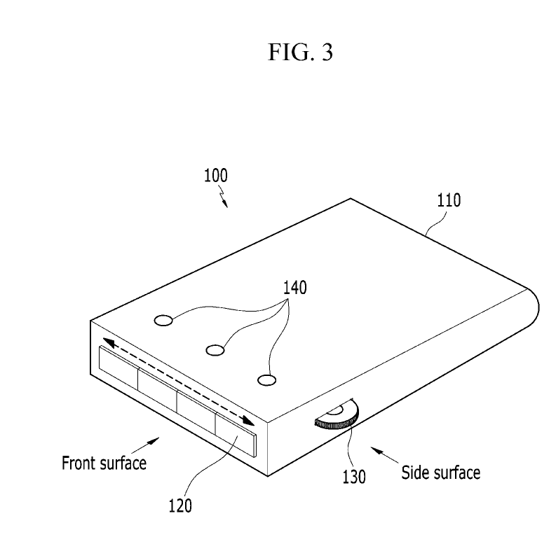

FIG. 3 is a perspective view illustrating a configuration of an integrated controller according to a second exemplary embodiment of the present invention.

A configuration of the integrated controller 100 according to a second exemplary embodiment of the present invention is similar to that of FIG. 3 and thus only differing portions of the front surface control unit 120 and the side surface control unit 130 will be described.

As shown in FIG. 3, the front surface control unit 120 includes two or more touch and push switch buttons 150 of an array form.

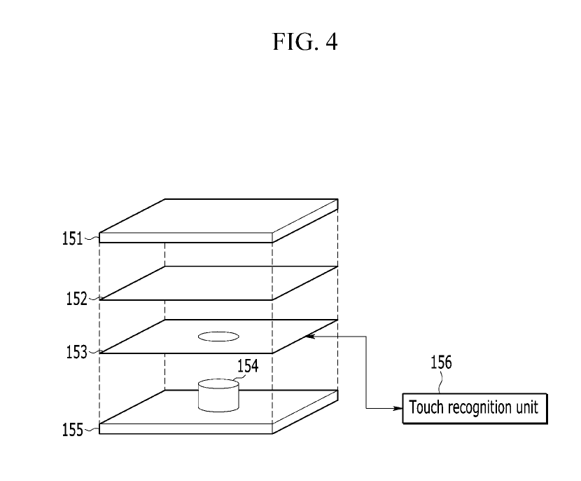

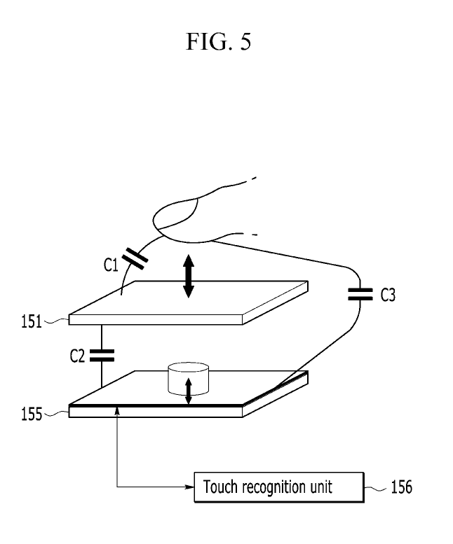

The touch and push switch button 150 will be described in detail with reference to FIG. 4 and FIG. 5.

FIG. 4 is a diagram illustrating a configuration of a touch and push switch button according to an exemplary embodiment of the present invention and FIG. 5 is a diagram illustrating a control method of a touch and push switch button according to an exemplary embodiment of the present invention.

As shown in FIG. 4, the touch and push switch button 150 according to an exemplary embodiment of the present invention includes a switch skin 151, a top metal electrode 152, a bottom metal electrode 153, a push switch protrusion 154, a push switch 155, and a touch recognition unit 156.

The switch skin 151 is disposed at an upper surface of the touch and push switch button 150 that a fingertip contacts.

The top metal electrode 152 is disposed at a lower portion of the switch skin 151.

Meanwhile, the push switch 155 is disposed at a lower surface of the touch and push switch button 150, and the push switch protrusion 154 is formed at a center of the push switch 155.

The push switch 155 may receive a physical pressure of the user through the push switch protrusion 154.

The bottom metal electrode 153 is disposed at an upper portion of the push switch 155, and formed with a penetration hole corresponding the push switch protrusion 154. In addition, the bottom metal electrode 153 is electrically connected to the touch recognition unit 156 to recognize a touch of the user.

That is, the push switch 155, the bottom metal electrode 153, the top metal electrode 152 and the switch skin 151 are sequentially stacked to form the touch and push switch button 150.

Referring to FIG. 5, the touch recognition unit 156 measures a capacitance by using the top metal electrode 152 and the bottom metal electrode 153, and detects the touch by comparing the capacitance while touch and non-touch.

That is, the switch skin 151 and the top metal electrode 152 are separately disposed form the bottom metal electrode 153 by the push switch protrusion 154. Thus, the touch recognition unit 156 measures a capacitance C1 between a finger and the metal electrode 152 and a capacitance C2 between the top metal electrode 152 and the bottom metal electrode 153, and calculates a total capacitance C3.

The total capacitance C3 is coupled in series, so the total capacitance C3 may be calculated by the following equation.

1/C3=1/C1+1/C2

When the total capacitance C3 is calculated, the touch recognition unit 156 may recognize the touch of the user by comparing the capacitance while touch and non-touch.

The touch and push switch button 150 of the front surface control unit 120 may be arranged in several sections to receive an input gesture such as flicking and swiping of a finger.

For example, each touch and push switch button 150 has a sequential ID, so right and left direction may be recognized depending on increase or decrease of the ID.

The side surface control unit 130 is located at a side surface of the case 110, and forms a scroll wheel in a portion that a thumb contacts.

A scroll wheel of the side surface control unit 130 includes a wheel button structure such as a mouse to support both scroll and input functions.

A detailed configuration of each integrated controller 100 that is described through the exemplary embodiments of FIGS. 2 and 3 is not limited thereto, and a portion of any control unit may be designed to have a different structure.

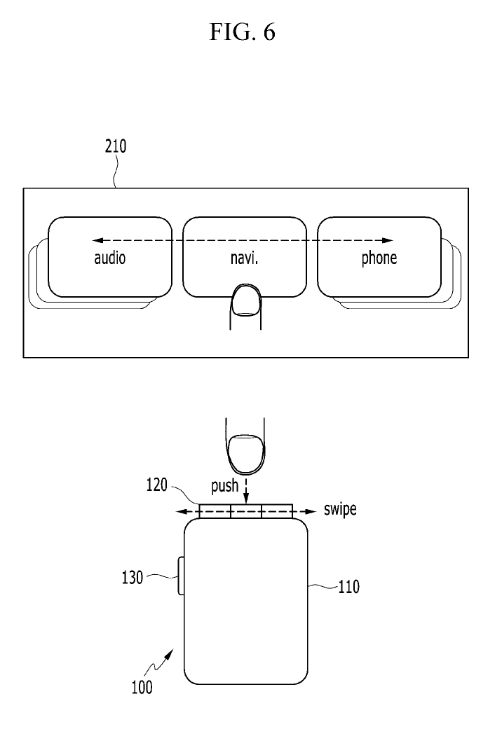

FIG. 6 is a diagram illustrating a simple UI that is displayed in a display unit and a control method of the same according to an exemplary embodiment of the present invention.

Referring to FIG. 6, because it is difficult for a driver to control a UI while operating a vehicle, the information processing device 200 is simply formed to have a simple UI displayed in the display unit 210.

For example, the information processing device 200 may use a simple UI that displays an icon of a general size and disposition when the vehicle stops, and that reduces the number of displayed icons and enlarges the size thereof while the vehicle is driven.

In this case, the simple UI is formed with three sections in consideration of the number of fingers that can control in the front surface control unit 120.

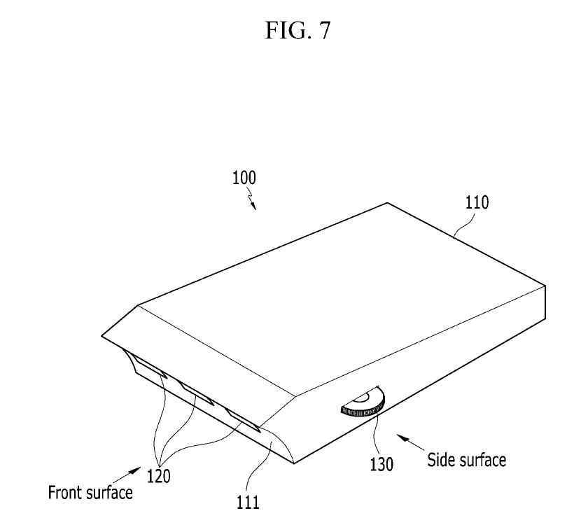

FIG. 7 is a perspective view illustrating a configuration of an integrated controller according to a third exemplary embodiment of the present invention.

A configuration of the integrated controller 100 according to the third exemplary embodiment of the present invention is similar to that of the foregoing exemplary embodiment, and thus only the shape of the case 110 and different portions of the front surface control unit 120 will be described.

As shown in FIG. 7, in the case 110 of the integrated controller 100 according to the third exemplary embodiment of the present invention, a slanted surface 113 is formed toward a lower portion from an upper surface and an inward rounded surface 111 rounded inward from the slanted surface 113 to a bottom surface.

In addition, the front surface control unit 120 is installed at the inward rounded surface 111 to be formed to more comfortably hold a finger grip. That is, when a user holds the integrated controller 100, a round state of a forefinger, a middle finger, and a ring finger is convenient for holding the integrated controller 100, and by installing the front surface control unit 120 at the inward rounded surface 111 of the case 110, control can be more comfortably performed. Further, by disposing the front surface control unit 120 at the inward rounded surface 111 of the case 110, malfunctions randomly controlled by other external objects can be prevented.

In the third exemplary embodiment of the present invention, the front surface control unit 120 may be formed with three touch and push switch buttons 150 corresponding to a forefinger, a middle finger, and a ring finger.

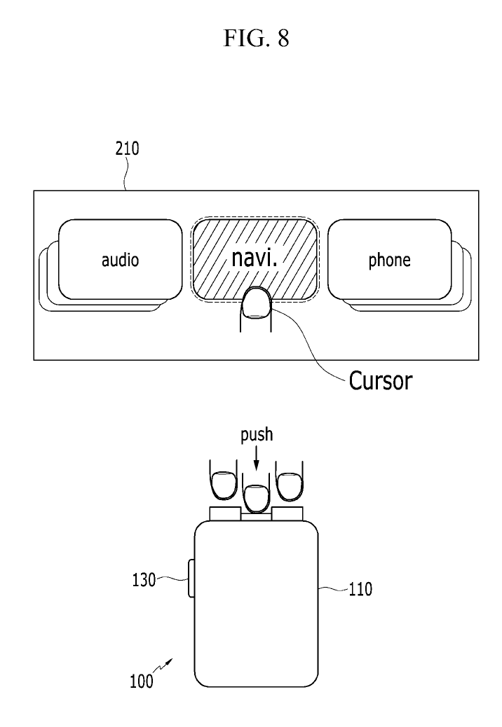

FIG. 8 is a diagram illustrating a control method of a front surface control unit according to the third exemplary embodiment of the present invention.

As shown in FIG. 8, the information processing device 200 displays a simple UI while a vehicle is driven.

Three touch and push switch buttons 150 of the front control unit 120 are interlocked with icons, respectively, of the displayed simple UI, and thus a user may selectively input three icons (audio, navi, and phone) using any one of a forefinger, a middle finger, and a ring finger.

In this case, it is preferable that an icon be selected to determine whether a button that is selected by the user and a target icon correspond, even if the user does not determine a button visually.

Therefore, a screen cursor is displayed at the display unit 210 and moved according to touch and swipe controls of a finger in the front surface control unit 120.

The cursor may freely move in an entire area of a screen according to finger control of the front control unit 120, or may move in an icon unit that is displayed in the display unit 210.

After that, when the user touches an intermediate button (navi) using a middle finger, haptic feedback is primarily displayed, and on a screen of the display unit 210, an icon (navi) corresponding to a touched button is displayed.

When the user presses the selected button (navi) with a middle finger, the information processing device 200 executes a navigation function of an icon that is interlocked therewith.

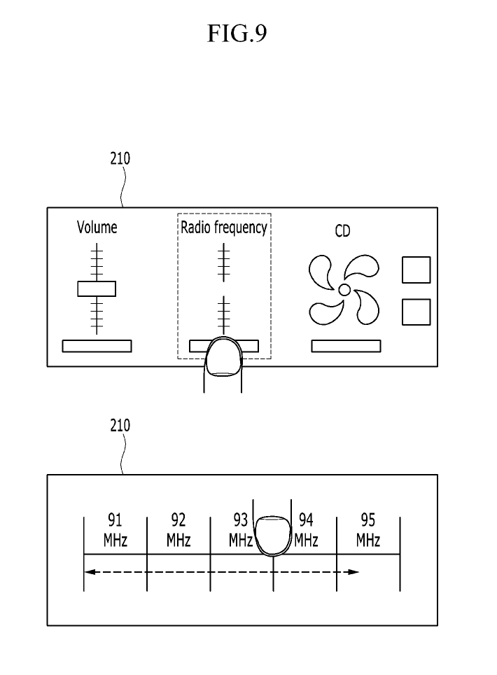

FIG. 9 is a diagram illustrating a simple UI that is displayed in a display unit and a control method of the same according to the third exemplary embodiment of the present invention.

As shown in FIG. 9, when the user selects an audio through the touch and push switch button 150, haptic feedback is primarily displayed, and on a screen of the display unit 210, an icon such as a volume, a radio frequency, and a CD are displayed.

In this case, when the user presses the touch and push switch button 150 corresponding to the radio frequency, the radio frequency is displayed.

At this time, the user may select the radio frequency by swiping gesture input.

In the foregoing description, various exemplary embodiments of the present invention are described, but the present invention is not limited to each exemplary embodiment, and a configuration of each exemplary embodiment can be substituted or other various changes can be performed.

For example, a case and button structure of the third exemplary embodiment may be applied even to the first exemplary embodiment and the second exemplary embodiment, and the side control unit 130 may be applied with a wheel method or an electrode array method in an entire exemplary embodiment.

In this way, according to an exemplary embodiment of the present invention, because a UI can be controlled with only a fingertip without moving a body or a hand, body convenience can be improved.

Further, gripping impression can be improved and entire control can be performed within a hand, and thus inconvenience of searching for a control system can be reduced. Line of sight and attention diversion problems accordingly can be solved.

Further, flicking and swiping input of a finger can be performed through a button array that can be touched, and thus a search list having a considerable amount of information can be easily performed.

An exemplary embodiment of the present invention may not only be embodied through the above-described apparatus and/or method, but may also be embodied through a program that executes a function corresponding to a configuration of the exemplary embodiment of the present invention or through a recording medium on which the program is recorded, and can be easily embodied by a person of ordinary skill in the art from a description of the foregoing exemplary embodiment.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. An integrated controller system for a vehicle, the integrated controller system comprising:
an information processing device that displays information for driving the vehicle through a display unit;
an integrated controller case that can be held with a hand;
a front surface control unit located at a front of the case that a holding fingertip contacts and that controls a User Interface (UI) displayed in the display unit;
a side surface control unit located at a side surface of the case that a holding fingertip contacts and that can perform scroll control of the UI;
a haptic feedback unit that transfers a haptic effect according to the UI control; and
a control unit that transfers a control signal according to the UI control to the information processing device.

2. The integrated controller system of claim 1, wherein the front surface control unit has a touch pad to control or select a particular UI with orthogonal motion and rotation.

3. The integrated controller system of claim 2, wherein the touchpad detects a touch location by measuring impedance associated with a finger with an electrode that is under a surface thereof.

4. The integrated controller system of claim 3, wherein the touchpad receives a menu selection with a double-tap method.

5. The integrated controller system of claim 1, wherein the front surface control unit has two or more touch and push switch buttons of an array form to control or select the particular UI with orthogonal motion and rotation.

6. The integrated controller system of claim 5, wherein the touch and push switch button comprises
a push switch formed with a protrusion;
a bottom metal electrode disposed at an upper portion of the push switch and formed with a penetration hole corresponding the protrusion;
a top metal electrode disposed at an upper portion of the bottom metal electrode;
a switch skin disposed at an upper portion of the top metal electrode and receiving a touch; and
a touch recognition unit connected to the bottom metal electrode.

7. The integrated controller system of claim 6, wherein the push switch, the bottom metal electrode, the top metal electrode and the switch skin are sequentially stacked.

8. The integrated controller system of claim 6, wherein the touch recognition unit recognizes the touch by detecting a capacitance between a finger and the bottom metal electrode.

9. The integrated controller system of claim 6, wherein the two or more touch and push switch buttons of the array form receive a flicking and swiping gesture input by a finger.

10. The integrated controller system of claim 1, wherein the side surface control unit has an electrode array or a scroll wheel button to receive a scrolling gesture input by a finger.

11. The integrated controller system of claim 1, wherein the haptic feedback unit comprises a haptic actuator that is disposed at an upper portion of the case that a palm in a holding state contacts.

12. The integrated controller system of claim 1, wherein the information processing device displays a simple UI that reduces an icon number to a predetermined number or less and that has an enlarged size on a screen of the display unit while a vehicle is driven.

13. The integrated controller system of claim 1, wherein the information processing device displays a cursor on a screen of the display unit, and the cursor freely moves in an entire area of a screen or moves in an icon unit that is displayed on a screen according to a finger control of the front surface control unit.

14. An integrated controller system for a vehicle, the integrated controller system comprising:
an information processing device that displays information for driving the vehicle through a display unit;
an integrated controller case that can be held with a hand;
a front surface control unit located at a front of the case that a holding fingertip contacts and provided with a plurality of touch and push switch button that controls a User Interface (UI) displayed in the display unit;
a side surface control unit located at a side surface of the case that a holding fingertip contacts and that can perform scroll control of the UI;
a haptic feedback unit that transfers a haptic effect according to the UI control; and
a control unit that transfers a control signal according to the UI control to the information processing device,
wherein a front surface of the case forms a slanted surface from an upper surface to a lower portion and an inward rounded surface from the slanted surface to a bottom surface, and the front surface control unit is installed at the slanted surface.

15. The integrated controller system of claim 14, wherein the touch and push switch button comprises
a push switch formed with a protrusion;
a bottom metal electrode disposed at an upper portion of the push switch and formed with a penetration hole corresponding the protrusion;
a top metal electrode disposed at an upper portion of the bottom metal electrode;
a switch skin disposed at an upper portion of the top metal electrode and receiving a touch; and
a touch recognition unit connected to the bottom metal electrode and recognizes the touch by detecting a capacitance between a finger and the bottom metal electrode.

16. The integrated controller system of claim 14, wherein the front surface control unit has three touch and push switch buttons corresponding to a forefinger, a middle finger, and a ring finger.

17. The integrated controller system of claim 16, wherein the information processing device displays a simple UI including three icons that have an enlarged size on a screen of the display unit while a vehicle is driven.

18. The integrated controller system of claim 17, wherein the three touch and push switch buttons are respectively interlocked with the three icons to receive any one icon operation.
